(19) United States
(12) Patent Application Publication
(10) Pub. No.: US 2024/0074205 A1
(43) Pub. Date: Feb. 29, 2024

(54) SEMICONDUCTOR MEMORY DEVICES AND METHODS OF MANUFACTURING THEREOF

(71) Applicant: Taiwan Semiconductor Manufacturing Company, Ltd., Hsinchu (TW)

(72) Inventors: Meng-Han Lin, Hsinchu City (TW); Chia-En Huang, Xinfeng Township (TW)

(73) Assignee: Taiwan Semiconductor Manufacturing Company, Ltd., Hsinchu (TW)

(21) Appl. No.: 17/896,745

(22) Filed: Aug. 26, 2022

(51) Int. Cl. H01L 27/1159

(52) U.S. Cl. CPC H01L 27/1159

(57) ABSTRACT

A semiconductor device includes a plurality of ferroelectric memory cells arranged over a substrate. Each of the plurality of ferroelectric memory cells includes: a first conductive structure extending along a first lateral direction and having a central portion and a pair of side portions, the side portions respectively extending away from the central portion along a second lateral direction perpendicular to the first lateral direction; a ferroelectric layer disposed above the first conductive structure and in contact with the central portion of the first conductive structure; a channel film disposed above a portion of the ferroelectric layer; a second conductive structure disposed above and in contact with the channel film; and a third conductive structure disposed above and in contact with the channel film.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example memory device, in accordance with some embodiments.

FIG. 2 illustrates an example polarization-voltage curve associated with a ferroelectric film of the memory device of FIG. 1, in accordance with some embodiments.

FIG. 3 is an example flow chart of a method for fabricating a memory device, in accordance with some embodiments.

FIGS. 4A, 5A, 6A, 7A, 8A, 9A, 10A, 11A, 12A, 13A, and 14A illustrate perspective views of an example memory device during various fabrication stages, made by the method of FIG. 3, in accordance with some embodiments.

FIGS. 4B, 5B, 6B, 7B, 8B, 9B, 10B, 11B, 12B, 13B, and 14B illustrate cross-sectional views of the memory device corresponding to FIGS. 4A to 14A, respectively, in accordance with some embodiments.

FIGS. 15, 16, 17, 18, 19, 20, 21, and 22 illustrate cross-sectional views of a WL structure of a memory device, made by the method of FIG. 3, respectively, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A ferroelectric material refers to a material that displays spontaneous polarization of electrical charges in the absence of an applied electric field. The net polarization P of electrical charges within the ferroelectric material is non-zero in the minimum energy state. Thus, spontaneous ferroelectric polarization of the material occurs, and the ferroelectric material accumulates surfaces charges of opposite polarity types on two opposing surfaces. Polarization P of a ferroelectric material as a function of an applied voltage V thereacross displays hysteresis. The product of the remanent polarization and the coercive field of a ferroelectric material is a metric for characterizing effectiveness of the ferroelectric material.

A ferroelectric memory device is a memory device containing the ferroelectric material which is used to store information. The ferroelectric material acts as the memory material of the memory device. The dipole moment of the ferroelectric material is programmed in two different orientations (e.g., “up” or “down” polarization positions based on atom positions, such as oxygen and/or metal atom positions, in the crystal lattice) depending on the polarity of the applied electric field to the ferroelectric material to store information in the ferroelectric material. The different orientations of the dipole moment of the ferroelectric material may be detected by the electric field generated by the dipole moment of the ferroelectric material.

For example, the ferroelectric memory device may be implemented as transistor structure, which includes the ferroelectric material interposed between a semiconductor channel and a word line (WL) structure. The WL structure can gate (e.g., modulate) the semiconductor channel to conduct current from a source line (SL) structure to a bit line (BL). The BL and SL structures are vertically disposed opposite the semiconductor channel from the WL structure, which can generally provide a decent channel resistance. However, the existing ferroelectric memory devices commonly suffer from the issues of high WL resistance and/or high SL/BL to WL capacitance. This is due to a trade-off between the limited width of the WL structure and undesired overlapping between the BL/SL structure and the WL structure. Thus, the existing ferroelectric memory devices have not been entirely satisfactory in many aspects.

The present disclosure provides various embodiments of a memory device that utilizes a ferroelectric material as its memory material. In various embodiments, the memory device can have a number of memory cells arranged as a two-dimensional (2D) memory array. Such a 2D memory array can include word line (WL) structures, functioning as respective gates of the memory cells, that each has its cross-section present in a cross shape. For example, the WL structure has a central portion and a pair of side portions, each of which extends away from the central portion in opposite directions. With such a cross shape, each of the WL structures can be isolated from bit line (BL) structures and source line (SL) structures of the memory array through a number of dielectric structures each filling a corner between the central portion and side portion. As such, parasitic capacitance induced between the WL structure and the BL/SL structure can be significantly depressed. Further, with the side portions respectively protruding away from the central portion, an equivalent width of the WL structure can be increased, which can advantageously decrease the corresponding WL resistance. Thus, the memory device, as disclosed herein, may be more suitable to operate with higher speed (due to, e.g., smaller RC delay), when compared to the existing ferroelectric memory devices.

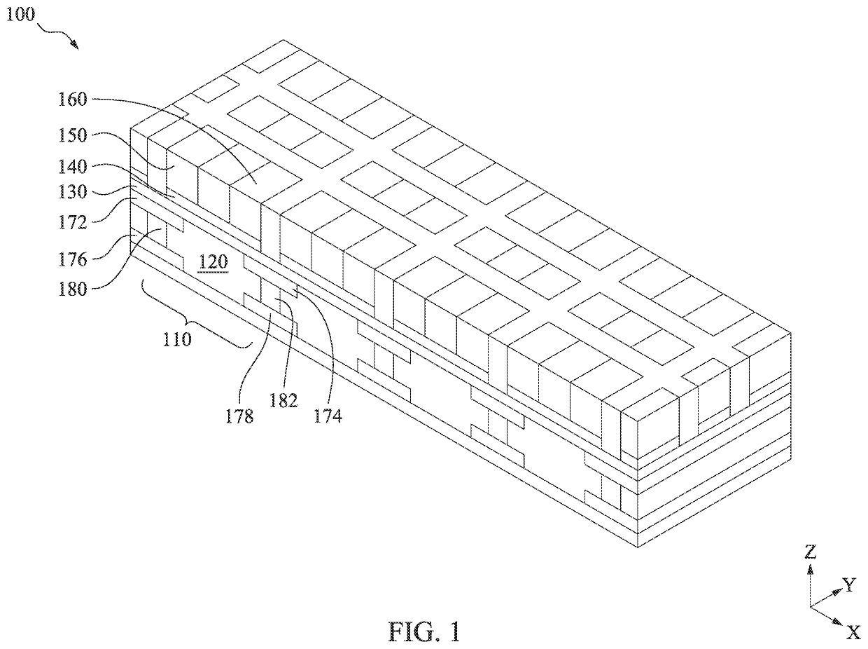

FIG. 1 illustrates a perspective view of a memory device 100, according to various embodiments of the present disclosure. It should be understood that the perspective view of FIG. 1 is simplified, and thus, it should be understood that any of various other features/components can also be included in FIG. 1, while remaining within the scope of the present disclosure. For example, a number of interconnect structures formed over the memory device 100 for routing the BL structures and SL structures are not shown.

As shown, the memory device 100 includes a number of memory cells 110 arranged as a memory array. The memory cells 110 shown in FIG. 1 may be formed within one memory layer, e.g., forming a two-dimensional (2D) memory array. It should be appreciated that, in some other embodiments, any number of such memory layers may be stacked on top of one another (e.g., along the Z direction) to form a memory array. Each of the memory cells 110 can include a laterally extending WL structure functioning as a gate to control a laterally extending channel film through a laterally extending ferroelectric film, and the channel film, on the other side of the ferroelectric film, is in electrical contact with a pair of laterally extending SL structure and BL structure, which will be discussed in further detail as follows.

For example, the memory device 100 includes a number of WL structures 120, each of which extends along the Y direction (e.g., 4 WL structures 120 in the example of FIG. 1). The WL structures 120 can each have its cross-section present in a cross shape, e.g., having a horizontal portion extending across the X direction and Y direction and a vertical portion extending across the Z direction and Y direction. Such horizontal and vertical portions can traverse across each other. Stated another way, the WL structures 120 each has a central portion and a pair of side portions, and the side portions extend away from the central portion, respectively, in the Y direction. The memory device 100 further includes a ferroelectric film 130 in contact with the WL structures 120. As shown, each of the WL structures 120 can be in contact with the ferroelectric film 130 through their respective central portions. The memory device 100 further includes a number of channel films 140. As shown, each of the WL structures 120 can be electrically coupled to a number of such channel films 140 that are arranged along the Y direction (e.g., 3 channel films 140 in the example of FIG. 1) through the ferroelectric film. The memory device 100 further includes a number of pairs of BL structures 150 and SL structures 160 that each extend along the Y direction. As shown, each of the channel films 140, on its opposite side coupled to the WL structure, is in contact with a corresponding pair of the BL structure 150 and SL structure 160.

The memory cell of the memory device 100 may be defined as a combination of one of the WL structures 120, a portion of the ferroelectric film 130, one of the channel films 140, and one of the pairs of BL structure 150 and SL structure 160. Such a memory cell may be implemented as a transistor structure (sometimes referred to as a “one-transistor (1T) structure”) with a gate, a gate oxide/dielectric layer, a semiconductor channel, a source, and a drain. The WL structure, the ferroelectric film, the channel film, the BL structure, and the SL structure may function as a gate, a gate dielectric layer, a semiconductor channel, a drain, and a source of the memory cell, respectively.

In various embodiments of the present disclosure, the memory device 100 can include a number of dielectric structures 172, 174, 176, 178, 180, and 182, each of which extends along the Y direction. As shown, the dielectric structure 172 is vertically interposed between one of the side portions of the WL structure 120 and the BL structure 150, and the dielectric structure 174 is vertically interposed between the other of the side portions of the WL structure 120 and the SL structure 160. Such dielectric structures 172 and 174 can advantageously help to decrease parasitic capacitance between the WL structure 120 and the BL structure 150/SL structure 160. The dielectric structures 180 and 182, in contact with respective sidewalls of the side portions of the WL structure 120, can electrically isolate the adjacent WL structures 120. The dielectric structures 176 and 178, which are vertically disposed below the side portions of the WL structure 120, respectively, can be optionally formed. The dielectric structures 180 and 182, together with the dielectric structures 176 and 178 (when formed), can collectively isolate a corresponding one of the WL structures 120 from another.

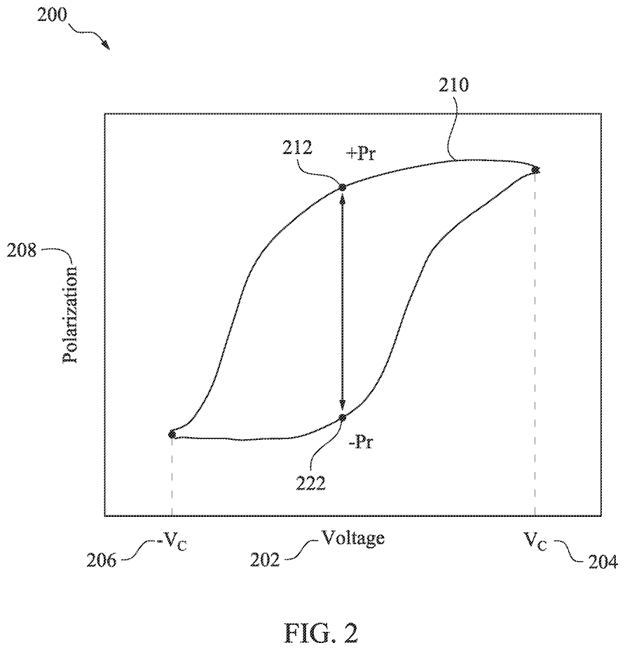

Referring to FIG. 2, depicted is a PV curve 200 associated with a ferroelectric film (e.g., 130), in accordance with some embodiments. The application of a coercive voltage (i.e., V_{C}) across electrodes of the ferroelectric film may result in polarization of the ferroelectric film. For example, the coercive voltage may be applied as a sweeping voltage across the corresponding WL structure (e.g., 120) and corresponding BL/SL structures (e.g., 150 and 160). The voltage axis 202 may be centered around any voltage, but in some embodiments will be centered around 0 volts and FIG. 2 will be referred to thusly. Applying a positive voltage to the ferroelectric film (e.g., a positive voltage applied to the WL structure with the BL/SL structures tied to ground), such as V_{C} 204, may saturate the polarization of the device, illustrated by a saturation point 214 on the PV curve 200, such that additional voltage may not result in substantial additional polarization. Another voltage (e.g., a voltage twice the magnitude of V_{C}) may result in a breakdown of the dielectric properties of the ferroelectric film (i.e., may be V_{BD}). In some embodiments, V_{BD} may be very close to V_{C}. In some embodiments, the voltage of the saturation point 214 may exceed that of V_{BD}, wherein a V_{C} of lesser amplitude than the saturation voltage may be selected, in order to avoid breakdown of the ferroelectric film. In some embodiments where V_{BD} exceeds the saturation voltage, a V_{C} may be selected in excess of the magnitude of the voltage of the saturation point 214. Adjusting the applied V_{C} 204 upward (i.e., approaching or exceeding the saturation point 214), may ensure a complete polarization of the device (which may result in increased performance and/or reliability), and adjusting the amplitude of the applied V_{C} 204 downward (i.e., increasing a margin to V_{BD}) may increase device longevity (e.g., may avoid electro-migration failures).

Following the application of V_{C} 204 to the ferroelectric film (e.g., by applying the voltage to two electrodes disposed on opposite sides of the film), V_{C} may be removed from the ferroelectric film. For example, the circuit may be opened, and the charges disposed along the two electrodes may gradually leak to normalize the voltage, or the ferroelectric film may be grounded (i.e., a ground voltage may be applied thereto). Upon reaching a ground state, the PV curve 200 may relax to a polarization point 212 (i.e., along the upper surface 210 of the PV curve 200). The application of a lower or higher voltage may result in a somewhat lower or higher polarization. Thus, the application of a plurality of magnitudes of V_{C} may result in a plurality of respective positive polarization point 212 values along a polarization axis 208. A plurality of discrete bit values, or a continuous value (e.g., an analog value or an undefined value used to generate random numbers) may be stored on the ferroelectric film. In some embodiments, a voltage may be applied to the ferroelectric film for an insufficient time to complete polarization, and thus polarization may also be controlled.

Application of a negative V_{C} 206 may polarize the ferroelectric film to a negative polarization point 222 when in a relaxed (e.g., ground) state. In some embodiments, the negative polarization point 222 and positive polarization point 212 may correspond to a logical “1” and logical “0,” respectively. In some embodiments, the ferroelectric film may be symmetrical or substantially symmetrical, wherein the magnitude of V_{C} 204 and —V_{C} 206 may be equal or substantially equal, whereas in other embodiments, the magnitude of V_{C} 204 may be substantially higher or lower than the magnitude of —V_{C} 206. In such embodiments, V_{C} may be applied directly to the ferroelectric film, and the difference in magnitude between V_{C} 204 and —V_{C} 206 may be due to intrinsic properties of the ferroelectric film. Alternatively or additionally, asymmetries between V_{C} 204 and —V_{C} 206 may be a result of additional circuit elements, such as a current sense resistors, capacitors, protection diodes, etc., which V_{C} 204/or and —V_{C} 206 may be applied to. Although V_{C} 204 and —V_{C} 206 may vary in amplitude and may comprise many values, V_{C} may be referred to generally herein, as to relate to any coercive voltage which may be intended to adjust the polarization of the ferroelectric film (e.g., a positive or negative value).

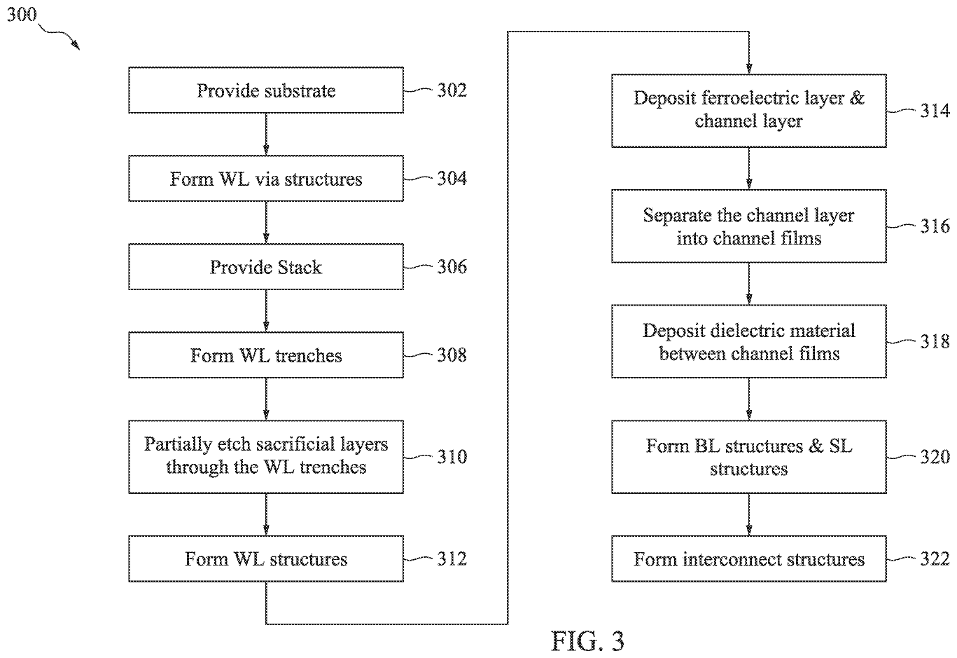

FIG. 3 illustrates a flowchart of a method 300 to form a memory device, according to various embodiments of the present disclosure. For example, at least some of the operations (or steps) of the method 300 can be performed to fabricate, make, or otherwise form a memory device (e.g., 100 of FIG. 1). The method 300 is merely an example, and is not intended to limit the present disclosure. Accordingly, it should be understood that additional operations may be provided before, during, and after the method 300 of FIG. 3, and that some other operations may only be briefly described herein.

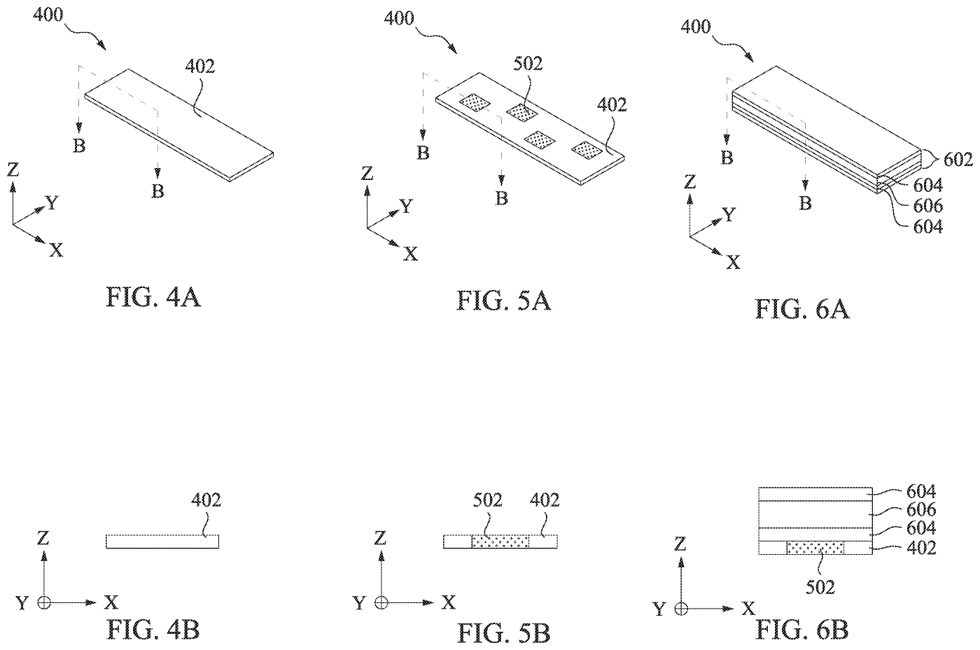

In various embodiments, operations of the method 300 may be associated with perspective views of an example memory device 400 at various fabrication stages as shown in FIGS. 4A, 5A, 6A, 7A, 8A, 9A, 10A, 11A, 12A, 13A, and 14A, respectively. Further, FIGS. 4B-14B illustrate cross-sectional views of a portion of the memory device 400 corresponding to the perspective view of FIGS. 4A-14A, respectively.

In brief overview, the method 300 starts with operation 302 of providing a substrate. The method 300 proceeds to operation 304 of forming word line (WL) via structures. The method 300 continues to operation 306 of providing a stack having one or more insulating layers and one or more sacrificial layers. The method 300 continues to operation 308 of forming a number of WL trenches. The method 300 continues to operation 310 of partially etching the sacrificial layer(s) through the WL trenches. The method 300 continues to operation 312 of forming a number of WL structures. The method 300 continues to operation 314 of sequentially depositing a ferroelectric layer and a channel layer. The method 300 continues to operation 316 of separating the channel layer into a number of channel films. The method 300 continues to operation 318 of depositing a dielectric material between the separated channel films. The method 300 continues to operation 320 of forming a number of bit line (BL) structures and a number of source line (SL) structures. The method 300 continues to operation 322 of forming a number of interconnect structures.

Corresponding to operation 302 of FIG. 3, FIGS. 4A and 4B illustrate a perspective view and a cross-sectional view of the memory device 400 in which a substrate 402 is provided, respectively, at one of the various stages of fabrication, in accordance with various embodiments. Specifically, the cross-sectional view of FIG. 4B illustrates a portion of the memory device 400 of FIG. 4A, e.g., cut along line B-B shown in FIG. 4A.

The substrate 402 may include an insulating or dielectric material. For example, the substrate 402 may be an intermetal dielectric (IMD) layer, which may be formed over a semiconductor substrate. A number of active/passive device features that collectively or respectively function as a logic circuit (e.g., transistors, capacitors, resistors, etc.) can be formed along a major surface of the semiconductor substrate. The IMD layer is deposited over the device features to embed a number of interconnect structures (e.g., conductive lines, vias) to electrically connect those device features. Those device features formed along the major surface of the semiconductor substrate are typically referred to as part of front-end-of-line (FEOL) networking/processing, and those interconnect structures formed over the device features are typically referred to as part of back-end-of-line (BEOL) networking/processing. In various embodiments, the memory device 400, as disclosed herein, may be formed within the BEOL networking. The dielectric material of such an IMD layer includes silicon oxide (SiO), silicon nitride (SiN), silicon oxynitride (SiON), dielectric material(s) with low dielectric constant (low-k) such as SiCOH, SiOCN, and/or SiOC, and/or a combination thereof. A low-k dielectric material is a dielectric material with a dielectric constant lower than about 3.9.

Corresponding to operation 304 of FIG. 3, FIGS. 5A and 5B illustrate a perspective view and a cross-sectional view of the memory device 400 in which a number of WL via structures 502 are formed in the substrate 402, respectively, at one of the various stages of fabrication, in accordance with various embodiments. Specifically, the cross-sectional view of FIG. 5B illustrates a portion of the memory device 400 of FIG. 5A, e.g., cut along line B-B shown in FIG. 5A.

The WL via structures 502 are formed to extend through the substrate 502. In various embodiments, the WL via structure 502 can each electrically couple one or more device features formed below the substrate 402 to a corresponding WL structure formed above the substrate 402, which will be discussed below. The WL via structures 502 can be formed through a damascene process, for example, etching the substrate 402 to form a number of via holes, filling those via holes with a metal material, and then performing a polishing process to remove excessive metal material. The metal material of the WL via structures 502 may include copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), and/or a combination thereof. The metal material can be deposited in the via holes (to form the WL via structures 502, respectively) through chemical vapor deposition (CVD), physical vapor deposition (PVD), atomic layer deposition (ALD), another suitable method, or a combination thereof.

Corresponding to operation 306 of FIG. 3, FIGS. 6A and 6B illustrate a perspective view and a cross-sectional view of the memory device 400 in which a stack 602 over the substrate 402, respectively, at one of the various stages of fabrication, in accordance with various embodiments. Specifically, the cross-sectional view of FIG. 6B illustrates a portion of the memory device 400 of FIG. 6A, e.g., cut along line B-B shown in FIG. 6A.

The stack 602 includes a number of insulating layers 604 and a number of sacrificial layers 606 alternately stacked on top of one another over the substrate 402 along a vertical direction (e.g., the Z direction). Although two insulating layers 604 and one sacrificial layer 606 are shown in the illustrated embodiments of FIGS. 6A-B, it should be understood that the stack 602 can include any number of insulating layers and any number of sacrificial layers alternately disposed on top of one another, while remaining within the scope of the present disclosure. As used herein, the alternately stacked insulating layers 604 and sacrificial layers 606 may refer to each of the sacrificial layers 606 being adjoined by two adjacent insulating layers 604. The insulating layers 604 may have the same thickness thereamongst, or may have different thicknesses. The sacrificial layers 606 may have the same thickness thereamongst, or may have different thicknesses. The stack 602 may begin with the insulating layer 604 (as shown in FIGS. 6A-B) or the sacrificial layer 606 (in some other embodiments).

The insulating layers 604 can include at least one insulating material. The insulating materials that can be employed for the insulating layer 604 include, but are not limited to, silicon oxide (including doped or undoped silicate glass), silicon nitride, silicon oxynitride, organosilicate glass (OSG), spin-on dielectric materials, dielectric metal oxides that are generally known as high dielectric constant (high-k) dielectric oxides (e.g., aluminum oxide, hafnium oxide, etc.) and silicates thereof, dielectric metal oxynitrides and silicates thereof, and organic insulating materials. Other insulating materials are within the scope of the present disclosure. In one embodiment, the insulating layers 604 include silicon oxide.

The sacrificial layers 606 may include an insulating material, a semiconductor material, or a conductive material. The material of the sacrificial layers 606 is a sacrificial material that can be subsequently removed selective to the material of the insulating layers 604. In some embodiments, each sacrificial layer 606, sandwiched by a respective pair of insulating layers 604, may correspond to a memory layer (or level), in which a number of memory cells that are laterally disposed from one another can be formed. For example, the stack 602, as shown in FIGS. 6A-B which includes one sacrificial layer 606, may form a single memory layer. However, in some other embodiments, other number of memory layers is still within the scope of the present disclosure.

Non-limiting examples of the sacrificial layers 606 include silicon nitride, an amorphous semiconductor material (such as amorphous silicon), and a polycrystalline semiconductor material (such as polysilicon). In one embodiment, the sacrificial layers 606 can be spacer material layers that include silicon nitride or a semiconductor material including at least one of silicon or germanium. Other materials are within the scope of the present disclosure.

The stack 602 can be formed by alternately depositing the respective materials of the insulating layers 604 and sacrificial layers 606 over the substrate 402. In some embodiments, one of the insulating layers 604 can be deposited, for example, by chemical vapor deposition (CVD), followed by depositing such as, for example, using CVD or atomic layer deposition (ALD), one of the sacrificial layers 606. Other methods of forming the stack 602 are within the scope of the present disclosure.

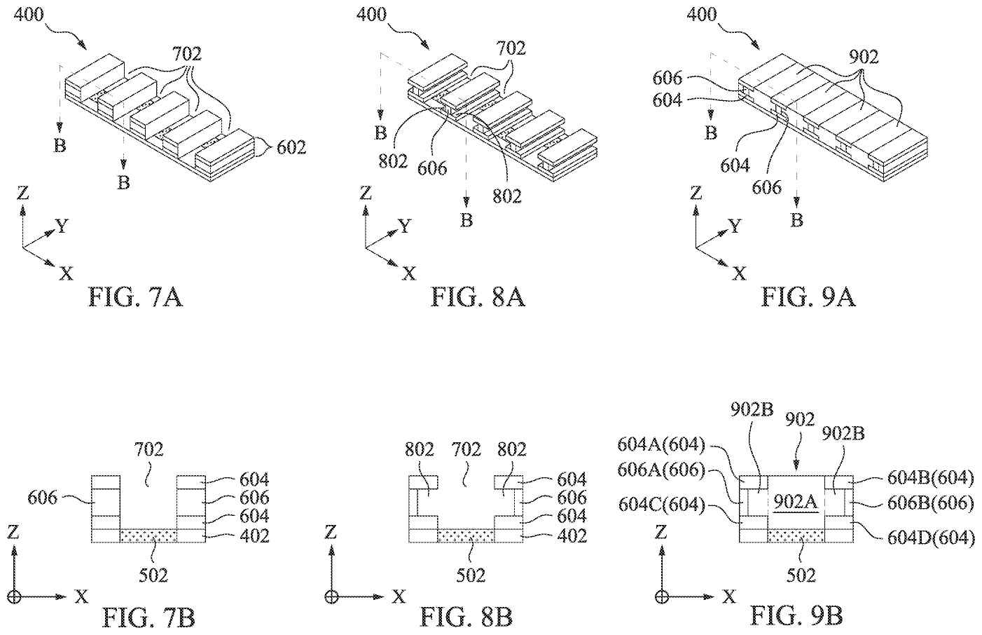

Corresponding to operation 308 of FIG. 3, FIGS. 7A and 7B illustrate a perspective view and a cross-sectional view of the memory device 400 in which a number of WL trenches 702 are formed in the stack 602, at one of the various stages of fabrication, in accordance with various embodiments. Specifically, the cross-sectional view of FIG. 7B illustrates a portion of the memory device 400 of FIG. 7A, e.g., cut along line B-B shown in FIG. 7A.

The WL trenches 702 are formed to extend along a same lateral direction (e.g., the Y direction) and spaced apart from one another along another lateral direction (e.g., the X direction), i.e., the WL trenches 702 are parallel with each other. The WL trenches 702 may be formed by at least an etching process to etch a number of portions of the stack 602. The etching process for forming the WL trenches 702 may include a plasma etching process, which can have a certain amount of anisotropic characteristic. For example, the WL trenches 702 may be formed, for example, by depositing a photoresist or other masking layer on a top surface of the stack 602, with a pattern corresponding to the WL trenches 702 defined in the masking layer (e.g., via photolithography, e-beam lithography, or any other suitable lithographic process). In other embodiments, a hard mask may be used.

Subsequently, the stack 602 may be etched using a plasma etching process (including radical plasma etching, remote plasma etching, and other suitable plasma etching processes, ME, DRIE), gas sources such as Cl₂, HBr, CF₄, CHF₃, CH₂F₂, CH₃F, C₄F₆, BCl₃, SF₆, Hz, NF₃, and other suitable etch gas sources and combinations thereof can be used with passivation gases such as N₂, O₂, CO₂, SO₂, CO, CH₄, SiCl₄, and other suitable passivation gases and combinations thereof. Moreover, for the plasma etching process, the gas sources and/or the passivation gases can be diluted with gases such as Ar, He, Ne, and other suitable dilutive gases and combinations thereof to form the WL trenches 702. In various embodiments, the etching process used to form the WL trenches 702 etches through each of the sacrificial layer 606 and insulating layers 604 of the stack 602 such that each of the WL trenches 702 can extend form the topmost insulating layer 604 through the bottommost insulating layer 604 to the substrate 402, as shown in the cross-sectional view of FIG. 7B.

Corresponding to operation 310 of FIG. 3, FIGS. 8A and 8B illustrate a perspective view and a cross-sectional view of the memory device 400 in which the sacrificial layers (or segments) 606 of the stack 602 are partially etched, at one of the various stages of fabrication, in accordance with various embodiments. Specifically, the cross-sectional view of FIG. 8B illustrates a portion of the memory device 400 of FIG. 8A, e.g., cut along line B-B shown in FIG. 8A.

Surfaces (or sidewalls) of the sacrificial layer 606 exposed by the WL trenches 702 are partially etched so as to reduce a width (e.g., along the X direction) of the sacrificial layer 606 relative to the corresponding insulating layers 604. For example, the sacrificial layer 606 is partially etched from their exposed surfaces facing toward or away from the X direction (sometimes referred to as an etching back process), thereby reducing a width of each of the sacrificial layer 606 along the X direction. In some embodiments, the sacrificial layer 606 may be etched using a wet etch process (e.g., hydrofluoric etch, buffered hydrofluoric acid). In other embodiments, the exposed surfaces of the sacrificial layer 606 may be partially etched using a plasma etching process (including radical plasma etching, remote plasma etching, and other suitable plasma etching processes, RIE, DRIE), gas sources such as Cl₂, HBr, CF₄, CHF₃, CH₂F₂, CH₃F, C₄F₆, BCl₃, SF₆, Hz, NF₃, and other suitable etch gas sources and combinations thereof can be used with passivation gases such as N₂, O₂, CO₂, SO₂, CO, CH₄, SiCl₄, and other suitable passivation gases and combinations thereof. Moreover, for the plasma etching process, the gas sources and/or the passivation gases can be diluted with gases such as Ar, He, Ne, and other suitable dilutive gases and combinations thereof.

Partially etching the sacrificial layer 606 in the X direction reduces a width of the sacrificial layer 606 relative to the insulating layers 604 disposed in the stack 602 such that a number of recesses 802 can be formed in the stack 602. Boundaries of each of such recess 802 are formed by top and bottom surfaces of adjacent insulating layers 604 and a surface of the partially etched sacrificial layer 606 that face the corresponding WL trenches 702. In various embodiments, the recess 802 each extend along a lateral direction (e.g., the Y direction).

Corresponding to operation 312 of FIG. 3, FIGS. 9A and 9B illustrate a perspective view and a cross-sectional view of the memory device 400 in which a number of WL structures 902 are formed, at one of the various stages of fabrication, in accordance with various embodiments. Specifically, the cross-sectional view of FIG. 9B illustrates a portion of the memory device 400 of FIG. 9A, e.g., cut along line B-B shown in FIG. 9A.

The WL structures 902A may be formed by filling the WL trenches 702 and the recesses 802 (FIGS. 8A-B) with a metal material. As such, the WL structures 902 each extend along a lateral direction (e.g., the Y direction). Further, the WL structures 902 can each have its cross-section present in a cross-shape, according to various embodiments of the present disclosure. As shown in the cross-sectional view of FIG. 9B, the WL structure 902 has a central portion 902A and a pair of side portions 902B. The side portions 902B extend away from a middle of the central portion 902A (e.g., along the X direction).

As such, a number of dielectric structures (e.g., formed by the insulating layers 604) can be present along a number of corners formed by the central portion and side portions. For example in FIG. 9B, a first dielectric structure 604A, extending along the Y direction, is present at the upper left corner; a second dielectric structure 604B, extending along the Y direction, is present at the upper right corner; a third dielectric structure 604C, extending along the Y direction, is present at the lower left corner; and a fourth dielectric structure 604D, extending along the Y direction, is present at the lower right corner. Further, each of the side portions 902B can have its sidewall in contact with a corresponding one of a number of dielectric structures (e.g., formed by the sacrificial layers 606). For example still in FIG. 9B, the side portion 902B on the left of the central portion 902A has its sidewall in contact with a fifth dielectric structure 606A extending along the Y direction; and the side portion 902B on the right of the central portion 902A has its sidewall in contact with a sixth dielectric structure 606B extending along the Y direction.

In some embodiments, each of the WL structures 902 is in (e.g., physical and/or electrical) contact with a corresponding one of the WL via structures 502, through its central portion 902A. Further, with the third and fourth dielectric structures 604C-D in presence (which may be optionally formed in some embodiments), the dielectric structures 604C-D may electrically isolate the side portions 902B from one or more other conductive features formed in the substrate 402. As will be shown below, a pair of SL structure and BL structure will be formed above the WL structure 902. With the first and second dielectric structures 604A-B vertically interposed between the side portions 902B and the SL-BL structures, parasitic capacitance between any of the SL-BL structures and the WL structure can be significantly reduced.

The metal material, used to form the WL structures 902, may be selected from the group consisting of copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), and a combination thereof. Other metal materials are within the scope of the present disclosure. The WL structures 902 can be formed by overlaying the workpiece with the above-listed metal material by, for example, CVD, PVD, ALD, electroless plating, electroplating, or combinations thereof. Prior to forming the WL structures 902, an adhesive layer may be conformally formed in the recesses 802 to enhance the adhesion between the materials of the sacrificial layer 606 and the WL structures 902. Further, following the deposition process of the WL structures 902, a polishing process may be performed to remove the excess metal material. Other methods of forming the WL structures 902 are within the scope of the present disclosure.

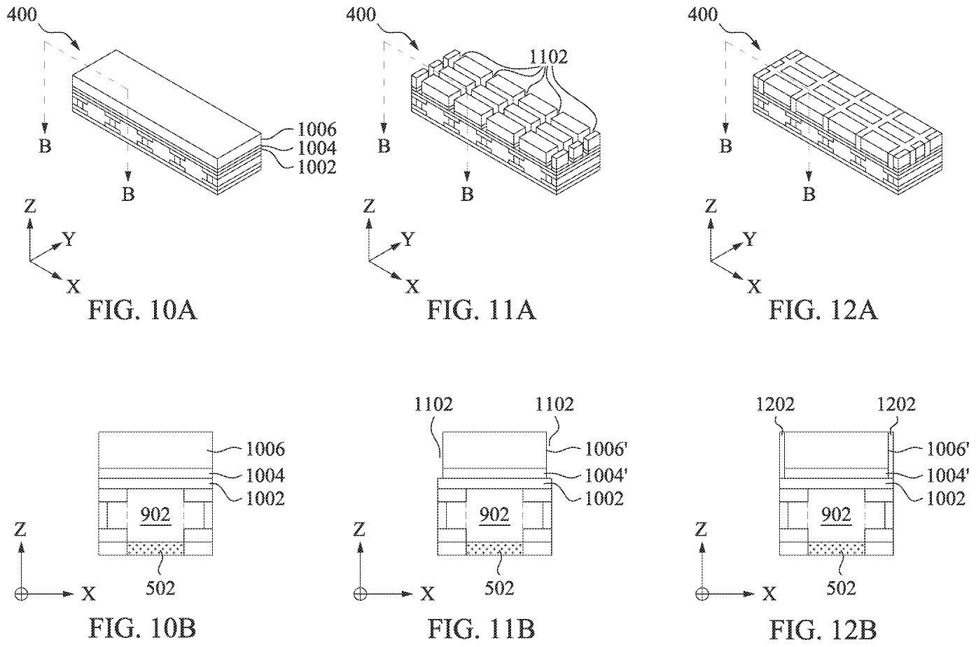

Corresponding to operation 314 of FIG. 3, FIGS. 10A and 10B illustrate a perspective view and a cross-sectional view of the memory device 400 in which a ferroelectric layer 1002, a channel layer 1004, and a dielectric layer 1006 are formed over the WL structures 902, at one of the various stages of fabrication, in accordance with various embodiments. Specifically, the cross-sectional view of FIG. 10B illustrates a portion of the memory device 400 of FIG. 10A, e.g., cut along line B-B shown in FIG. 10A.

The ferroelectric layer 1002, channel layer 1004, and dielectric layer 1006 may be sequentially deposited over the workpiece, e.g., each of which is formed as a blanket layer. The ferroelectric layer 1002 can include one or more ferroelectric materials. The channel layer 1004 can include one or more semiconductor materials. The dielectric layer 1006 can include one or more insulating materials similar to the insulating layers 604.

The foregoing ferroelectric material, used to form the ferroelectric layer 1002, includes, and/or consists essentially of, at least one ferroelectric material such as hafnium oxide (such as hafnium oxide containing at least one dopant selected from Al, Zr, and Si and having a ferroelectric non-centrosymmetric orthorhombic phase), zirconium oxide, hafnium-zirconium oxide, bismuth ferrite, barium titanate (such as BaTiO₃; BT), colemanite (such as Ca₂B₆O₁₁·5H₂O), bismuth titanate (such as Bi₄Ti₃O₁₂), europium barium titanate, ferroelectric polymer, germanium telluride, langbeinite (such as M₂M′₂(SO₄)₃ in which M is a monovalent metal and M′ is a divalent metal), lead scandium tantalate (such as Pb(ScₓTa₁₋ₓ)O₃), lead titanate (such as PbTiO₃; PT), lead zirconate titanate (such as Pb (Zr,Ti) O₃; PZT), lithium niobate (such as LiNbO₃; LN), (LaAlO₃)), polyvinylidene fluoride (CH₂CF₂)ₙ, potassium niobate (such as KNbO₃), potassium sodium tartrate (such as KNaC₄H₄O₆·4H₂O), potassium titanyl phosphate (such as KO₅PTi), sodium bismuth titanate (such as Na_{0.5}Bi_{0.5}TiO₃ or Bi_{0.5}Na_{0.5}TiO₃), lithium tantalate (such as LiTaO₃(LT)), lead lanthanum titanate (such as (Pb,La)TiO₃(PLT)), lead lanthanum zirconate titanate (such as (Pb,La)(Zr,Ti)O₃ (PLZT)), ammonium dihydrogen phosphate (such as NH₄H₂PO₄(ADP)), or potassium dihydrogen phosphate (such as KH₂PO₄(KDP)).

The foregoing semiconductor material, used to form the channel layer 1004, may include a doped or undoped semiconductor material such as, for example, Si (e.g., polysilicon or amorphous silicon), Ge, SiGe, silicon carbide (SiC), indium gallium zinc oxide (IGZO), indium tin oxide (ITO), indium zinc oxide (IZO), indium tungsten oxide (IWO), or combinations thereof. The semiconductor material can be deposited (as a blanket layer) over the workpiece as a continuous liner structure, for example, by a conformal deposition method such as atomic layer deposition (ALD) or chemical vapor deposition (CVD). Other deposition methods are within the scope of the present disclosure.

Corresponding to operation 316 of FIG. 3, FIGS. 11A and 11B illustrate a perspective view and a cross-sectional view of the memory device 400 in which the channel layer 1004 and the dielectric layer 1006 are patterned, at one of the various stages of fabrication, in accordance with various embodiments. Specifically, the cross-sectional view of FIG. 11B illustrates a portion of the memory device 400 of FIG. 11A, e.g., cut along line B-B shown in FIG. 11A.

In various embodiments, the channel layer 1004 and the dielectric layer 1006 may be concurrently patterned to form a number of separated (or isolated) channel films 1004′, each of which is overlaid by a corresponding one of separated (or isolated) dielectric films 1006′. For example, the channel films 1004′ (and the dielectric films 1006′) are formed by dividing, cutting, or otherwise patterning each of the continuously extending channel layer 1004 and dielectric layer 1006 into a respective number of discrete portions. These “cut” discrete portions (e.g., the channel films 1004′) are spaced apart from each other along the Y direction and along the X direction, as shown. In various embodiments, the channel films 1004′ (and the dielectric films 1006′) may be formed by performing at least some of the following processes: forming a patterned mask layer over the dielectric layer 1006 that at least exposes respective portions of the dielectric layer 1006 where openings 1102 are located (or defined); and using the mask layer to perform at least one etching process to remove the exposed portions of the dielectric layer 1006 and channel layer 1004. As such, each of the channel films 1004′ may have its (e.g., four) sides surrounded by the openings 1102. During the formation of the channel films 1004′, the ferroelectric layer 1002 may remain substantially intact.

Corresponding to operation 318 of FIG. 3, FIGS. 12A and 12B illustrate a perspective view and a cross-sectional view of the memory device 400 in which the openings 1102 are filled with a dielectric material 1202, at one of the various stages of fabrication, in accordance with various embodiments. Specifically, the cross-sectional view of FIG. 12B illustrates a portion of the memory device 400 of FIG. 12A, e.g., cut along line B-B shown in FIG. 12A. The dielectric material 1202 can have a similar material to the dielectric films 1006′.

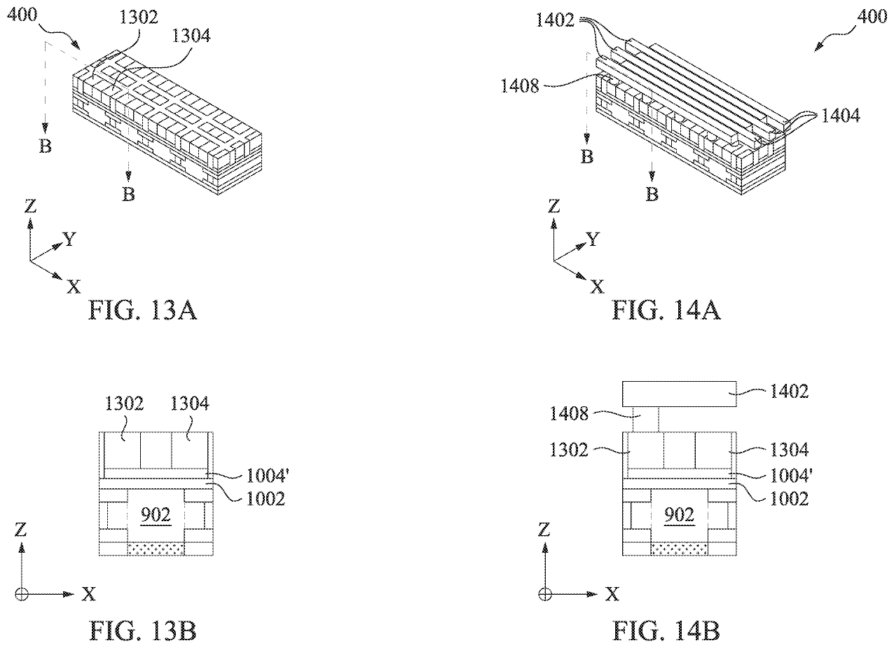

Corresponding to operation 320 of FIG. 3, FIGS. 13A and 13B illustrate a perspective view and a cross-sectional view of the memory device 400 in which a number of BL structures 1302 and a number of SL structures 1304 are formed, at one of the various stages of fabrication, in accordance with various embodiments. Specifically, the cross-sectional view of FIG. 13B illustrates a portion of the memory device 400 of FIG. 13A, e.g., cut along line B-B shown in FIG. 13A.

The BL structures 1302 and SL structures 1304 are formed to extend along the Y direction, and a respective pair of the BL structure 1302 and SL structure 1304 may be formed over a corresponding one of the channel films 1004′. Specifically, each pair of the BL structure 1302 and SL structure 1304 may extend along the Y direction with a length that is about the same as an extending width/length of the corresponding channel film 1004′, and the BL structure 1302 and SL structure 1304 may have their respective sidewalls (facing toward or away from the X direction) aligned with the sidewalls of the corresponding channel film 1004′ (facing toward or away from the X direction).

The BL structures 1302 and SL structures 1304 are each formed of a metal material. An example metal material may be selected from the group consisting of copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), and a combination thereof. The BL structures 1302 and SL structures 1304 may be formed by performing at least some of the following processes: forming a patterned mask layer over the dielectric films 1006′ that at least exposes respective end portions of each of the dielectric films 1006′; using the mask layer to perform at least one etching process to remove the exposed portions thereby forming a number of recesses; depositing one of the foregoing metal materials (through, for example, CVD, PVD, ALD, electroless plating, electroplating, or combinations thereof) in the recesses to form the BL structures 1302 and SL structures 1304; and polishing the workpiece.

Corresponding to operation 322 of FIG. 3, FIGS. 14A and 14B illustrate a perspective view and a cross-sectional view of the memory device 400 in which a number of interconnect structures 1402 and 1404 are formed, at one of the various stages of fabrication, in accordance with various embodiments. Specifically, the cross-sectional view of FIG. 14B illustrates a portion of the memory device 400 of FIG. 14A, e.g., cut along line B-B shown in FIG. 14A.

The interconnect structure 1402 may be formed to electrically couple all the BL structures 1302 to each other, and the interconnect structure 1404 may be formed to electrically couple all the SL structures 1304 to each other. Each of the interconnect structures 1402 and 1404 is coupled to the respective BL structures 1302 or SL structures 1304 through a respective number of via structures 1408. The interconnect structures 1402 and 1404 may all extend along the X direction, and are in parallel with one another, as shown in FIG. 14A. In some embodiments, the interconnect structure 1402 and interconnect structure 1404 may sometimes be referred to as a global BL and a global SL, respectively. The interconnect structures 1402 and 1404 are each formed of a metal material. An example metal material may be selected from the group consisting of copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), and a combination thereof.

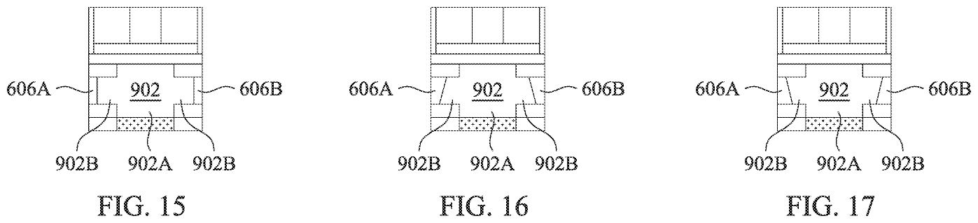

In some embodiments, the WL structure 902 can have its cross-section formed in any of various other profiles. FIGS. 15, 16, 17, 18, 19, 20, 21, and 22 illustrate different cross-sections of the WL structure 902, respectively. Such different cross-sections of the WL structure 902 may be formed during one of the various fabrication stages of the memory device 400, for example, operation 310 in which the sacrificial layers 606 of the stack 602 are partially etched.

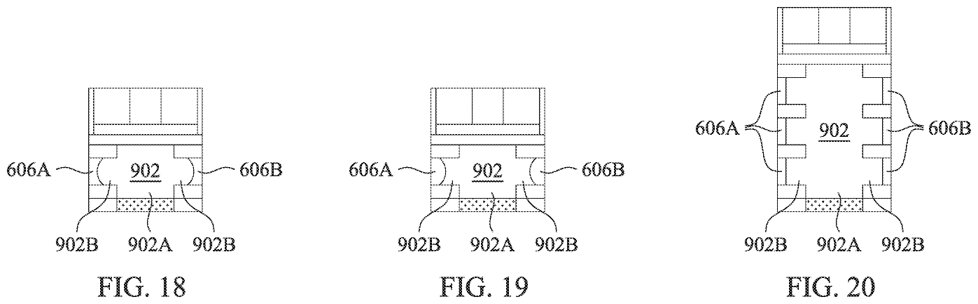

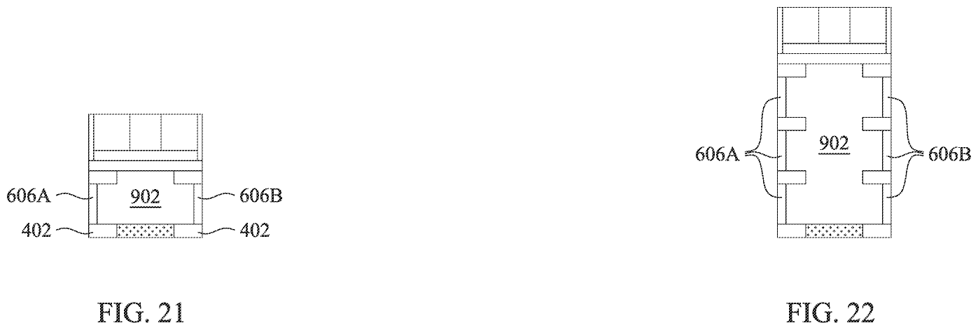

Throughout FIGS. 15 to 22, the WL structure 902 has its side portions 902B in contact with the dielectric structures 606A and 606B, respectively. Further, in FIG. 15, an interface between a sidewall of the side portion 902B and the dielectric structure 602A/B has a nearly vertical profile (i.e., along the Z direction). In FIG. 16, such an interface is tilted from the vertical direction, e.g., tilted toward the central portion 902A with an increasing height of the side portion 902B. Therefore, the side portions 902B and a part of the central portion 902A may form a trapezoidal cross-section. In FIG. 17, such an interface is tilted from the vertical direction, e.g., tilted away from the central portion 902A with an increasing height of the side portion 902B. Therefore, the side portions 902B and a part of the central portion 902A may form a reverse-trapezoidal cross-section. In FIG. 18, such an interface has a curvature-based profile, e.g., rounded outward from the central portion 902A. In FIG. 19, such an interface has a curvature-based profile, e.g., rounded inward to the central portion 902A. In FIG. 20, the WL structure 902 has multiple levels of the side portions 902B in contact with different pairs of the dielectric structures 606A and 606B, respectively. The interface between the side portion 902B and the dielectric structure 606A/B may have a nearly vertical profile. However, the interface can have any of various other profiles, as herein disclosed. In FIG. 21, the dielectric structure 606A/B may be in direct contact with the underlying substrate 402, i.e., no dielectric structure formed between the dielectric structure 606A/B and the substrate 402. In FIG. 22, the dielectric structure 606A/B may also be in direct contact with the underlying substrate 402, but there are multiple levels of the pairs of the dielectric structure 606A and 606B.

In one aspect of the present disclosure, a semiconductor device is disclosed. The semiconductor device includes a first word line (WL) structure extending along a first lateral direction, wherein the first WL structure has a central portion and a pair of side portions, and wherein the pair of side portions of the first WL structure extend away from the central portion of the first WL structure along a second lateral direction, respectively. The semiconductor device includes a ferroelectric layer disposed above the first WL structure. The semiconductor device includes a plurality of first channel films disposed above the ferroelectric layer and separated from one another along the first lateral direction. The semiconductor device includes a plurality of first source line (SL) structures separated from one another along the first lateral direction, wherein each of the first SL structures is disposed above a corresponding one of the first channel films. The semiconductor device includes a plurality of first bit line (BL) structures separated from one another along the first lateral direction, wherein each of the first BL structures is disposed above a corresponding one of the first channel films.

In another aspect of the present disclosure, a semiconductor device is disclosed. The semiconductor device includes a plurality of ferroelectric memory cells arranged over a substrate. Each of the plurality of ferroelectric memory cells includes: a first conductive structure extending along a first lateral direction and having a central portion and a pair of side portions, the side portions respectively extending away from the central portion along a second lateral direction perpendicular to the first lateral direction; a ferroelectric layer disposed above the first conductive structure and in contact with the central portion of the first conductive structure; a channel film disposed above a portion of the ferroelectric layer; a second conductive structure disposed above and in contact with the channel film; and a third conductive structure disposed above and in contact with the channel film.

In yet another aspect of the present disclosure, a method for fabricating memory devices is disclosed. The method includes forming a word line (WL) structure extending along a first lateral direction. The WL structure has a central portion and a pair of side portions, and the side portions respectively extend away from the central portion along a second lateral direction perpendicular to the first lateral direction. The method includes forming a ferroelectric layer over the WL structure. The method includes forming, over the ferroelectric layer, a plurality of first channel films separated from one another. The method includes forming a plurality of source line (SL) structures and a plurality of bit line (BL) structures over the plurality of first channel films. Each of the plurality of first channel films is in contact with a corresponding one of the SL structures and a corresponding one of the BL structures.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first word line (WL) structure extending along a first lateral direction, wherein the first WL structure has a central portion and a pair of side portions, and wherein the pair of side portions of the first WL structure extend away from the central portion of the first WL structure along a second lateral direction, respectively;
a ferroelectric layer disposed above the first WL structure;
a plurality of first channel films disposed above the ferroelectric layer and separated from one another along the first lateral direction;
a plurality of first source line (SL) structures separated from one another along the first lateral direction, wherein each of the first SL structures is disposed above a corresponding one of the first channel films; and
a plurality of first bit line (BL) structures separated from one another along the first lateral direction, wherein each of the first BL structures is disposed above a corresponding one of the first channel films.

2. The semiconductor device of claim 1, further comprising:
a first dielectric structure extending along the first lateral direction and vertically disposed between a first one of the side portions and the ferroelectric layer;
a second dielectric structure extending along the first lateral direction and vertically disposed between a second one of the side portions and the ferroelectric layer;
a third dielectric structure extending along the first lateral direction and vertically disposed below the first side portion; and
a fourth dielectric structure extending along the first lateral direction and vertically disposed below the second side portion.

3. The semiconductor device of claim 2, wherein the first dielectric structure and second dielectric structure are in contact with first portions of sidewalls of the central portion, respectively, and the third dielectric structure and fourth dielectric structure are in contact with second portions of the sidewalls of the central portion, respectively.

4. The semiconductor device of claim 3, wherein the first portion and the second portion of each sidewall of the central portion are spaced apart from each other by either the first or second side portion.

5. The semiconductor device of claim 1, further comprising:
a second WL structure extending along the first lateral direction, wherein the second WL structure has a central portion and a pair of side portions, and wherein the pair of side portions of the second WL structure extend away from the central portion of the second WL structure along a second lateral direction, respectively;
a plurality of second channel films disposed above the ferroelectric layer and separated from one another along the first lateral direction;
a plurality of second SL structures separated from one another along the first lateral direction, wherein each of the second SL structures is disposed above a corresponding one of the second channel films; and
a plurality of second BL structures separated from one another along the first lateral direction, wherein each of the second BL structures is disposed above a corresponding one of the second channel films.

6. The semiconductor device of claim 5, wherein the ferroelectric layer is also disposed between the plurality of second channel films and the second WL structure.

7. The semiconductor device of claim 5, further comprising:
a first dielectric structure extending along the first lateral direction and disposed between the central portion of the first WL structure and the central portion of the second WL structure; and
a second dielectric structure extending along the first lateral direction and disposed between the central portion of the first WL structure and the central portion of the second WL structure;
wherein the first dielectric structure and second dielectric structure are vertically spaced from each other with a first one of the side portions of the first WL structure and a first one of the side portions of the second WL structure.

8. The semiconductor device of claim 7, further comprising a third dielectric structure extending along the first lateral direction, wherein the third dielectric structure is interposed between the first side portion of the first WL structure and the first side portion of the second WL structure.

9. The semiconductor device of claim 8, wherein an interface between the third dielectric structure and at least one of the first portion of the first WL structure or the first portion of the second WL structure is tilted from a direction perpendicular to the first and second lateral directions.

10. The semiconductor device of claim 8, wherein an interface between the third dielectric structure and at least one of the first portion of the first WL structure or the first portion of the second WL structure has a curvature-based profile.

11. The semiconductor device of claim 1, wherein the first WL structure, the ferroelectric layer, one of the first channel films, one of the first SL structures, and one of the first BL structures operatively function as a memory cell.

12. A semiconductor device, comprising:
a plurality of ferroelectric memory cells arranged over a substrate;
wherein each of the plurality of ferroelectric memory cells includes:
a first conductive structure extending along a first lateral direction and having a central portion and a pair of side portions, the side portions respectively extending away from the central portion along a second lateral direction perpendicular to the first lateral direction;
a ferroelectric layer disposed above the first conductive structure and in contact with the central portion of the first conductive structure;
a channel film disposed above a portion of the ferroelectric layer;
a second conductive structure disposed above and in contact with the channel film; and
a third conductive structure disposed above and in contact with the channel film.

13. The semiconductor device of claim 12, wherein the second and third conductive structures, in parallel with each other, extend along the first lateral direction.

14. The semiconductor device of claim 12, wherein, in the first lateral direction, the second and third conductive structures each have its ends aligned with the channel film.

15. The semiconductor device of claim 12, wherein the first conductive structure is shared by a plural number of the ferroelectric memory cells arranged along the first lateral direction.

16. The semiconductor device of claim 12, wherein a sidewall of each of the side portions is tilted from a direction perpendicular to the first and second lateral directions.

17. The semiconductor device of claim 12, wherein a sidewall of each of the side portions has a curvature-based profile.

18. A method for manufacturing a memory device, comprising:
forming a word line (WL) structure extending along a first lateral direction, wherein the WL structure has a central portion and a pair of side portions, and the side portions respectively extend away from the central portion along a second lateral direction perpendicular to the first lateral direction;
forming a ferroelectric layer over the WL structure;
forming, over the ferroelectric layer, a plurality of first channel films separated from one another; and
forming a plurality of source line (SL) structures and a plurality of bit line (BL) structures over the plurality of first channel films, wherein each of the plurality of first channel films is in contact with a corresponding one of the SL structures and a corresponding one of the BL structures.

19. The method of claim 18, prior to forming the WL structure, further comprising:
forming a first dielectric structure, a second dielectric structure, and a third dielectric structure;
wherein the first to third dielectric structures all extend along the first lateral direction, and the second dielectric structure is vertically disposed between the first and second dielectric structures.

20. The method of claim 18, wherein the first dielectric structure is vertically disposed between one of the side portions and the ferroelectric layer, the second dielectric structure is in contact with a sidewall of the side portion, and third dielectric structure is vertically disposed below the side portion.
